(19) United States
(12) Patent Application Publication
(10) Pub. No.: US 2021/0217913 A1
(43) Pub. Date: Jul. 15, 2021

(54) FLEXIBLE PHOTOVOLTAIC MODULE

(71) Applicant: Miasole Equipment Integration (Fujian) Co., Ltd., Fujian (CN)

(72) Inventors: Pengchen HU, Fujian (CN); Jianqing WU, Fujian (CN); Libing LIU, Fujian (CN); Tao LI, Fujian (CN); Shan YI, Fujian (CN); Yihuan WANG, Fujian (CN); Zhaoxiong HUANG, Fujian (CN)

(21) Appl. No.: 16/089,541

(22) PCT Filed: Jul. 2, 2018
(86) PCT No.: PCT/CN2018/094114

§ 371 Date: Sep. 28, 2018

(30) Foreign Application Priority Data
Dec. 12, 2017 (CN) 201721723574.7

(51) Int. Cl. H01L 31/048

(52) U.S. Cl. CPC H01L 31/0481; H01L 31/03926

(57) ABSTRACT

A flexible photovoltaic module is provided. The flexible photovoltaic module includes a front plate, a solar cell and a back plate. The front plate, the solar cell and the back plate are arranged from top to bottom. The solar cell includes a polyethylene terephthalate (PET) based film arranged on a side of the solar cell close to the front plate. The PET based film includes a first adhesive layer arranged on a side of the PET based film close to the front plate. The back plate includes a second adhesive layer arranged on a side of the back plate close to the solar cell.

The present disclosure claims priority to Chinese patent application No. 201721723574.7, filed on Dec. 12, 2017, entitled “Flexible Photovoltaic Module”, the disclosure of which is incorporated herein by reference in its entirety.

### TECHNICAL FIELD

The present disclosure relates to the field of solar cell, and in particular to a flexible photovoltaic module.

### BACKGROUND

Flexible solar cell has become a dominant solar cell due to its features such as light weight, easy installation and replacement and strong shape adaptability and the like.

From bottom to top, the flexible photovoltaic module includes a back plate, an aluminum back plate, an edge sealing butyl adhesive, a lower packaging film, a bus bar or a diode, an upper packaging film and a front plate. Both the thickness of the upper encapsulation film and the lower encapsulation film range from 200 microns to 400 microns. The flexible photovoltaic module adopts both the upper packaging film and lower packaging film, which increases the complexity of the process and increase the equipment and human cost.

### SUMMARY

The present disclosure provides a flexible photovoltaic module, which can solve the foregoing problems, simplify the processing technology of the flexible photovoltaic module and reduce the equipment and human cost.

A flexible photovoltaic module includes a front plate, a solar cell and a back plate, which are arranged from top to bottom.

The solar cell includes a polyethylene terephthalate (PET) based film arranged on a side of the solar cell close to the front plate, and the PET based film includes a first adhesive layer arranged on a side of the PET based film close to the front plate.

The back plate includes a second adhesive layer, and the second adhesive layer is arranged on a side of the back plate close to the solar cell.

In the flexible photovoltaic module described above, the solar cell further includes a copper electrode winding layer, a PN junction multilayer film and a flexible substrate, which are arranged successively below the PET based film, and the flexible substrate is arranged on a side of the solar cell close to the back plate.

In the flexible photovoltaic module described above, the flexible substrate includes a metal foil substrate.

In the flexible photovoltaic module described above, the flexible substrate is made from one or more materials of iron, nickel, coper, aluminum, tungsten, molybdenum.

In the flexible photovoltaic module described above, the PET based film further includes a first PET layer and a third adhesive layer, which are arranged below the first adhesive layer; and the third adhesive layer is arranged on a side of the PET based film close to the copper electrode winding layer.

In the flexible photovoltaic module described above, the back plate further includes a second PET layer, an aluminum foil layer and a third PET layer, which are successively arranged below the second adhesive layer, and the second PET layer is arranged on a side of the back plate facing away from the battery piece.

In the flexible photovoltaic module described above, the first adhesive layer includes a resin adhesive layer.

In the flexible photovoltaic module described above, the second adhesive layer includes one of an ethylene-vinyl acetate copolymer (EVA) layer, polyvinyl butyral film (PVB) layer, a polyolefin elastomer resin (POE) layer or a thermoplastic organosilicon layer.

In the flexible photovoltaic module described above, the thickness of the first adhesive layer is 100 microns to 150 microns.

In the flexible photovoltaic module described above, the thickness of the second adhesive layer is 100 microns to 150 microns.

In the flexible photovoltaic module described above, the first adhesive layer is configured to bond the solar cell and the front plate, and the second adhesive layer is configured to bond the back plate and the solar cell.

In the flexible photovoltaic module described above, the PET based film is laminated on the copper electrode winding layer to form a composite structure layer, the composite structure layer, the PN junction multilayer film and the flexible substrate are directly laminated to form the solar cell.

In the flexible photovoltaic module described above, the PN junction multilayer film comprises a front electrode layer, a window layer or a buffer layer, an absorption layer and a back electrode, wherein the front electrode layer, the window layer or buffer layer, the absorption layer and the back electrode are successively arranged from top to bottom, the front electrode layer is arranged at a side close to the PET based film, and the back electrode layer is arranged at a side close to the flexible substrate.

In the flexible photovoltaic module described above, a thickness of the first PET layer is 50 microns.

In the flexible photovoltaic module described above, the third adhesive layer comprises a resin adhesive layer, and a thickness of the third adhesive layer is 25 microns.

In the flexible photovoltaic module described above, a thickness of the second adhesive layer ranges from 100 microns to 150 microns.

In the flexible photovoltaic module described above, a thickness of the aluminum foil layer ranges from 20 microns to 50 microns.

In the flexible photovoltaic module described above, material of the front plate comprises PET or fluoropolymer, and the fluoropolymer comprises Ethylene-tetrafluoroethylene (ETFE), Ethylene-chlorotrifluoroethylene copolymer (ECTFE), Fluorinated ethylene propylene (FEP), or Polyvinylidene fluoride (PVDF).

This present disclosure provides a flexible photovoltaic module, which avoids the procedures of forming an upper encapsulation film and a lower encapsulation film in the process of manufacturing flexible photovoltaic module. A PET based film with a thick first adhesive layer instead the upper encapsulation film is used in the manufacturing the solar cell. In the process of manufacturing the back plate, a second adhesive layer is integrated on the back plate, so as to avoid using a separate lower encapsulation film, thereby simplifying the process of laminated flexible photovoltaic module and reducing the cost of equipment and human cost at the same time.

In an embodiment, the thickness of the first adhesive layer is 100 microns to 150 microns and provides sufficient bonding force for the solar cell and the front plate, ensuring the structural strength of the flexible photovoltaic module. The thickness of the second adhesive layer is 100 microns to 150 microns and provides sufficient bonding force for the solar cell and the back plate, ensuring the structural strength of the flexible photovoltaic module.

In an embodiment, the thickness of the aluminum foil layer ranges from 20 microns to 50 microns and ensures an excellent water resistance performance.

### BRIEF DESCRIPTION OF DRAWINGS

FIG. 1 is a structure diagram of a flexible photovoltaic module according to an embodiment of the present disclosure;

FIG. 2 is a structure diagram of a solar cell of a flexible photovoltaic module according to an embodiment of the present disclosure;

FIG. 3 is a structure diagram of a polyethylene terephthalate based film of a flexible photovoltaic module according to an embodiment of the present disclosure;

FIG. 4 is a structure diagram of a back plate of a flexible photovoltaic module according to an embodiment of the present disclosure; and

FIG. 5 is a structure diagram of a PN junction multilayer film of a flexible photovoltaic module.

### DETAILED DESCRIPTION

The following describes the embodiments of the present disclosure, examples of the embodiments are shown in drawings, and the same or similar reference numerals throughout represent the same or similar elements or elements with the same or similar functions. The embodiments described below by referring to the drawings are exemplary.

Annotation: PET is short for Polyethylene terephthalate; EVA is short for Ethylene-vinyl acetate copolymer; PVB is short for Polyvinyl butyral film; and POE is short for Polyolefin elastomer resin.

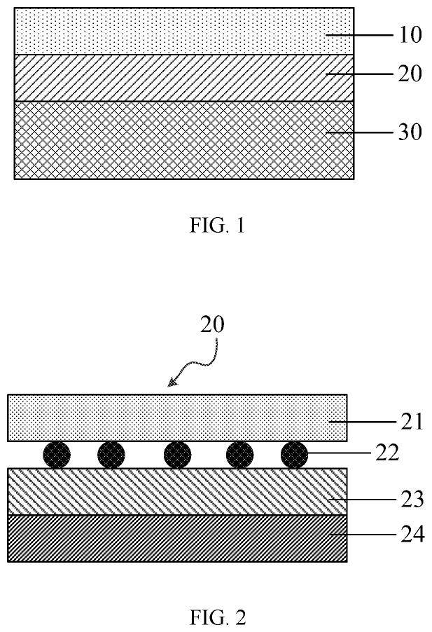

FIG. 1 is a structure diagram of a flexible photovoltaic module according to an embodiment of the present disclosure. The flexible photovoltaic module provided in this embodiment includes a front plate 10, a solar cell 20 and a back plate 30. The front plate 10, the solar cell 20 and the back plate 30 are arranged from top to bottom.

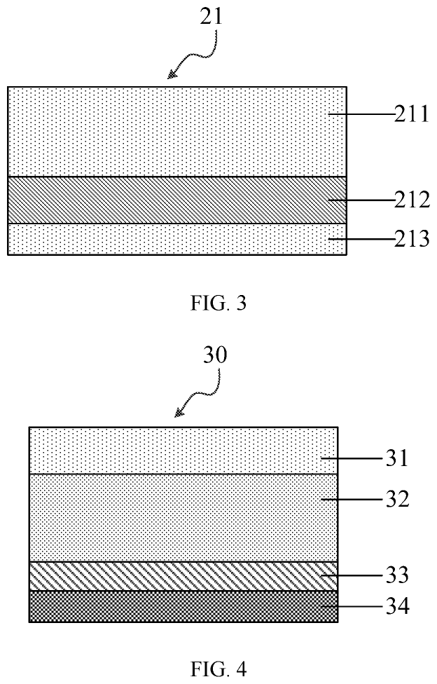

FIG. 2 is a structure diagram of the solar cell of the flexible photovoltaic module according to an embodiment of the present disclosure. The solar cell 20 includes a polyethylene terephthalate (PET) based film 21. FIG. 3 is a structure diagram of the PET based film of the flexible photovoltaic module according to an embodiment of the present disclosure. The PET based film 21 is arranged on a side of the solar cell 20 close to the front plate 10, and the PET based film 21 includes a first adhesive layer 211. The first adhesive layer 211 is arranged on a side of the PET based film 21 close to the front plate 10. FIG. 4 is a structure diagram of the back plate of the flexible photovoltaic module according to an embodiment of the present disclosure. The back plate 30 includes a second adhesive layer 31, and the second adhesive layer 31 is arranged on a side of the back plate 30 close to the solar cell 20.

In one embodiment, the front plate 10 may be made from modified Polyethylene terephthalate (PET), or fluoropolymer, such as Ethylene-tetrafluoroethylene (ETFE), Ethylene-chlorotrifluoroethylene copolymer (ECTFE), Fluorinated ethylene propylene (FEP), or Polyvinylidene fluoride (PVDF) and other high polymer materials with high optical transmittance, low water vapor transmittance and excellent ultraviolet radiation resistance.

According to the flexible photovoltaic module provided in this embodiment, the solar cell 20 is integrated with the first adhesive layer 211, and the first adhesive layer 211 is configured to bond the solar cell 20 and the front plate 10, the back plate 30 is integrated with the second adhesive layer 31, and the second adhesive layer 31 is configured to bond the back plate 30 and the solar cell 20. Comparing with the related arts, the procedures of providing an upper encapsulation film and a lower encapsulation film are not needed in the process of manufacturing the flexible photovoltaic module. A PET based film 21 with a thick first adhesive layer 211 instead the upper encapsulation film is used, in the process of manufacturing solar cell 20. In the process of manufacturing the back plate 30, the back plate 30 is integrated with the second adhesive layer 31, so as to avoid using a separate lower encapsulation film, simplifying the process of manufacturing the flexible photovoltaic module and reducing the cost of equipment and human cost at the same time.

In one embodiment, from top to bottom, the solar cell 20 successively includes the PET based film 21, a copper electrode winding layer 22, a PN junction multilayer film 23 and a flexible substrate 24. The flexible substrate 24 is arranged on a side close to the back plate 30. In the process of manufacturing, the PET based film 21 is laminated on the copper electrode winding layer 22 to form a composite structure layer. In the subsequent process of manufacturing the solar cell 20, the composite structure layer, the PN junction multilayer film 23 and the flexible substrate 24 are directly laminated to form the solar cell 20.

From top to bottom, the PET based film 21 successively includes the first adhesive layer 211, a first PET layer 212 and a third adhesive layer 213. The first adhesive layer 211 includes a resin adhesive layer, and the thickness of the first adhesive layer may be 100 microns to 150 microns. The thickness of the first PET layer 212 may be 50 microns. The third adhesive layer 213 is the resin adhesive layer, and the thickness of the third adhesive layer 213 may be 25 microns.

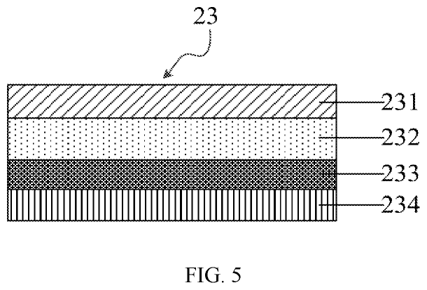

FIG. 5 is a structure diagram of the PN junction multilayer film of the flexible photovoltaic module. From top to bottom, the PN junction multilayer film 23 successively includes a front electrode layer 231, a window layer or a buffer layer 232, an absorption layer 233 and a back electrode 234. The front electrode layer 231 is arranged at a side close to the PET based film 21 and the back electrode layer is arranged at a side close to the flexible substrate 24.

In one embodiment, the flexible substrate 24 includes a metal foil substrate made from one or more materials of iron (Fe), nickel (Ni), copper (Cu), aluminum (Al), tungsten (W), molybdenum (Mo).

In one embodiment, from top to bottom, the back plate successively includes the second adhesive layer 31, a second PET layer 32, an aluminum foil layer 33 and a third PET layer 34. The third PET layer 34 is arranged on a side of the back plate 30 facing away from the solar cell 20. The second adhesive layer 31 includes one of an EVA material layer, a PVB material layer, a POE material layer or a thermoplastic organosilicon layer, and the thickness of the second adhesive layer 31 may be 100 microns to 150 microns. The second adhesive layer 31 provides sufficient adhesion between the back plate 30 and the battery piece 20, so as to ensure the structural strength of the flexible photovoltaic module. The thickness of the second PET layer 32 may be 150 microns to 250 microns, and the second PET layer 32 ensures good insulation between the conductive part inside the flexible photovoltaic module and the outside world. The aluminum foil layer 33 may be 20 microns to 50 microns, and the aluminum foil layer 33 ensures that the back plate 30 has excellent water resistance performance. The third PET layer 34 is made from high weatherability PET materials.

Comparing with the related arts, the integrated back plate 30 provided in this embodiment simplifies the manufacture process, saves raw materials and reduces production costs. For the flexible photovoltaic module, the integrated back plate 30 reduces the complexity of the process, reduces the cost, and is more conducive to automation.

1. A flexible photovoltaic module, comprising a front plate, a solar cell and a back plate, wherein the front plate, the solar cell and the back plate are arranged from top to bottom;
the solar cell comprises a polyethylene terephthalate (PET) based film, the PET based film is arranged on a side of the solar cell close to the front plate, the PET based film comprises a first adhesive layer, the first adhesive layer is arranged on a side of the PET based film close to the front plate; and
the back plate comprises a second adhesive layer, the second adhesive layer is arranged on a side of the back plate close to the solar cell.

2. The flexible photovoltaic module according to claim 1, wherein the solar cell further comprises a copper electrode winding layer, a PN junction multilayer film and a flexible substrate, the copper electrode winding layer, the PN junction multilayer film and the flexible substrate are arranged successively below the PET based film, and the flexible substrate is arranged on a side of the solar cell close to the back plate.

3. The flexible photovoltaic module according to claim 2, wherein the flexible substrate comprises a metal foil substrate.

4. The flexible photovoltaic module according to claim 2, wherein the flexible substrate is made from one or more materials of iron, nickel, copper, aluminum, tungsten and molybdenum.

5. The flexible photovoltaic module according to claim 2, wherein the PET based film further comprises a first PET layer and a third adhesive layer, the first PET layer and the third adhesive layer are arranged below the first adhesive layer; and the third adhesive layer is arranged on a side of the PET based film close to the copper electrode winding layer.

6. The flexible photovoltaic module according to claim 2, wherein the back plate further comprises a second PET layer, an aluminum foil layer and a third PET layer, the second PET layer, the aluminum foil layer and the third PET layer are successively arranged below the second adhesive layer, and the second PET layer is arranged on a side of the back plate facing away from the solar cell.

7. The flexible photovoltaic module according to claim 1, wherein the first adhesive layer comprises a resin adhesive layer.

8. The flexible photovoltaic module according to claim 1, wherein the second adhesive layer comprises an ethylene-vinyl acetate copolymer (EVA) layer, a polyvinyl butyral film (PVB) layer, a polyolefin elastomer resin (POE) layer or a thermoplastic organosilicon layer.

9. The flexible photovoltaic module according to claim 1, wherein a thickness of the first adhesive layer ranges from 100 microns to 150 microns.

10. The flexible photovoltaic module according to claim 1, wherein a thickness of the second adhesive layer ranges from 100 microns to 150 microns.

11. The flexible photovoltaic module according to claim 1, wherein the first adhesive layer is configured to bond the solar cell and the front plate, and the second adhesive layer is configured to bond the back plate and the solar cell.

12. The flexible photovoltaic module according to claim 2, wherein the PET based film is laminated on the copper electrode winding layer to form a composite structure layer, the composite structure layer, the PN junction multilayer film and the flexible substrate are directly laminated to form the solar cell.

13. The flexible photovoltaic module according to claim 2, wherein the PN junction multilayer film comprises a front electrode layer, a window layer or a buffer layer, an absorption layer and a back electrode, wherein the front electrode layer, the window layer or buffer layer, the absorption layer and the back electrode are successively arranged from top to bottom, the front electrode layer is arranged at a side close to the PET based film, and the back electrode layer is arranged at a side close to the flexible substrate.

14. The flexible photovoltaic module according to claim 5, wherein a thickness of the first PET layer is 50 microns.

15. The flexible photovoltaic module according to claim 5, wherein the third adhesive layer comprises a resin adhesive layer, and a thickness of the third adhesive layer is 25 microns.

16. The flexible photovoltaic module according to claim 6, wherein a thickness of the second adhesive layer ranges from 100 microns to 150 microns.

17. The flexible photovoltaic module according to claim 6, wherein a thickness of the aluminum foil layer ranges from 20 microns to 50 microns.

18. The flexible photovoltaic module according to claim 1, wherein material of the front plate comprises PET or fluoropolymer, and the fluoropolymer comprises Ethylene-tetrafluoroethylene (ETFE), Ethylene-chlorotrifluoroethylene copolymer (ECTFE), Fluorinated ethylene propylene (FEP), or Polyvinylidene fluoride (PVDF).
